(19) United States
(12) Patent Application Publication
(10) Pub. No.: US 2006/0284208 A1
(43) Pub. Date: Dec. 21, 2006

(54) Light emitting diode device using electrically conductive interconnection section

(76) Inventors: Jong Hoon Kang, Seoul (KR); Jae Seung Lee, Daejeon (KR); Bu Gon Shin, Daejeon (KR); Duk Sik Ha, Cheongju-si (KR); Min Ho Choi, Pohang-si (KR); Min A Yu, Daejeon (KR)

Correspondence Address: MCKENNA LONG & ALDRIDGE LLP, 1900 K STREET, NW, WASHINGTON, DC, 20006, US

(21) Appl. No.: 11/246,076

(22) Filed: Oct. 11, 2005

(30) Foreign Application Priority Data
Jun. 15, 2005 (KR) 2005-51335

(51) Int. Cl. H01L 33/00

(52) U.S. Cl. 257/100

(57) ABSTRACT

A light emitting diode devic that includes (a) a light emitting diode section, (b) an electrically conductive pad section being disposed outside the light emitting diode section and being electrically connected to an external power source, and (c) at least one electrically conductive interconnection section for connecting the electrically conductive pad section to one side or both sides of the light emitting diode section. In the light emitting diode device, a wire is connected to the electrically conductive pad section disposed outside the light emitting diode section, and the electrically conductive pad section is connected to one side of the light emitting diode section by means of at least one electrically conductive interconnection section, so that not only it is easy to uniformly coat a fluorescent substance, but also an area covering vertically emitted light can be reduced to enhance a light extraction efficiency of the light emitting diode device.

This application claims the benefit of the filing date of Korean Patent Application No. 10-2005-0051335, filed on 15, Jun. 2005, in the Korean Intellectual Property Office, the disclosure of which is incorporated herein in its entirely by reference.

### BACKGROUND OF THE INVENTION

1. Field of the Invention

The present invention relates to a light emitting diode device in which an electrically conductive pad section to be electrically connected to an external power source is disposed outside a light emitting diode section and is connected to one side or both sides of the light emitting diode section by means of at least one electrically conductive interconnection section, a manufacturing method thereof, and a light emitting unit with such a light emitting diode device.

2. Description of the Related Art

A light emitting diode (LED) device is a semiconductor device which generates light by flowing a forward current through a PN junction.

A sapphire substrate 8 is mainly used for growing gallium nitride (GaN)-based compound semiconductor for the manufacture of a light emitting diode. Sapphire substrates are electrically isolated, so that the anode 1 and cathode 2 of LEDs are formed on the front face of a wafer. In general, a low-output GaN-based light emitting diode is manufactured in such a manner that a sapphire substrate 8, on which a crystal structure is grown, is put on a lead frame 5 and then the two electrodes 1, 2 are connected to an upper portion of the sapphire substrate 8. At this time, in order to improve a heat discharging efficiency, the sapphire substrate 8 is bonded onto the lead frame 4 after reducing its thickness to become approximately 100 μm or less. This is schematically shown in FIG. 1. Thermal conductivity of sapphire substrates 8 is approximately 50 W/m·K. Therefore, even if the thickness is reduced to be about 100 μm, it has a high thermal resistance. On the contrary, in a case of a gallium nitride-based light emitting diode with high output, there is a tendency to mainly use a flip chip bonding method in order to more improve a heat discharging characteristic.

In the flip-chip bonding method, a chip with an LEDs structure is bonded to a sub-mount 10, such as silicon wafer (150 W/m·K) having superior thermal conductivity or an AIN ceramic substrate (about 180 W/m·K), with its inner surface facing out, and FIG. 2 schematically shows this method. In such a flip chip structure, since heat is emitted through the sub-mount substrate 10, a heat discharging efficiency is improved as compared with a case of heat discharging through the sapphire substrate 8, but there is a problem in that its manufacturing process is complicated and the heat discharging still leaves more to be desired.

In order to solve the above-mentioned problems, a Laser Lift-Off (LLO)-type manufacturing method of a light emitting diode comes into the spotlight. Manufacturing an LED by means of the laser lift-off method is known to generate the most excellent structure for enhancing the heat discharging efficiency by irradiating laser toward a sapphire substrate 8, on which the LED has grown, and removing the sapphire substrate 8 from the LED's crystal structure before packaging. Also, the LED manufactured by the laser lift-off method has a better light extraction property because the light emitting area becomes almost equal to the size of chips (in a case of the flip chip, the light emitting area corresponds to about 60% of the size of chips).

Meanwhile, a manufacturing technology of a white light emitting diode can be largely divided into two methods. One of them is a single-chip method in which a fluorescent material is joined on a blue LED chip or an UV LED chip to obtain white color, and the other is a multi-chip method in which two or three LED chips are combined with each other to obtain white color. In the single-chip method, it is essentially required to coat a fluorescent substance on a prepared light emitting diode.

A method of mixing a fluorescent substance 18 with a molding material such as silicon or epoxy is mainly used for coating the fluorescent substance 18, but such a method has a difficulty in uniformly dispersing the fluorescent substance 18. To cope with this, a dispersant may be used, but it is difficult to actually apply the dispersant to the coating of the fluorescent substance because the fluorescent substance 18 frequently deteriorated by the dispersant solvent. Recently, there has been developed a coating method in which the fluorescent substance 18 is coated in the form of a thin film on a light emitting diode. For example, such a coating method includes micro dispensing, stencil, chemical reaction coating, silkscreen and so forth. In forming the thin film of the fluorescent substance 18, it is preferred that the upper portion of the light emitting diode section to be coated with the thin film has no unevenness. However, when a wire 9 is bonded to the upper portion of the light emitting diode section, it is not easy to coat the fluorescent substance without injuring the wire 9.

In manufacturing a light emitting diode device, the pattern area of a bonding pad is taken into consideration for wire bonding of the wire 9. However, when a wire bonding section consisting of the bonding pad and the wire 9 is disposed over the light emitting diode section, there is a disadvantage in that it covers a vertical light emitting area of the light emitting diode. That is, an area of about 0.1×0.1 mm² is required for the wire bonding of the wire 9, which means that the wire bonding area covers a light emitting area by 1/9 in a 0.3×0.3 mm² chip. In addition, the overall chip area tends to become larger as a light emitting diode has higher output, and the number of ohmic metal pads may increase in order to reduce electrical resistance as occasion demands. Of course, in a high-output light emitting diode which is driven at a high current, heat accumulation can be prevented by reducing series resistance, and a light emission efficiency can be enhanced by thickly depositing the ohmic contact metal to prevent a voltage drop. However, there is a limit to the thick deposition of metal, and the area of the bonding pad over the light emitting diode section cannot but increase in order to prevent performance lowering of the light emitting diode due to the voltage drop within the ohmic contact metal. In result, the problem of a decrease in the vertical light emitting area of LED cannot be avoided.

### SUMMARY OF THE INVENTION

Considering the above-mentioned problems, the present invention is directed to not only facilitating uniform coating of a fluorescent substance, but also effectively enhancing a light extraction efficiency of a light emitting diode by reducing an ohmic contact area absorbing light vertically come out of the light emitting diode. To this end, instead of a wire bonding section which is conventionally disposed over a light emitting diode section and thus causes a decrease in a vertical light emitting area and a difficulty in coating a fluorescent substance, an electrically conductive pad section is disposed outside the light emitting diode section and then at least one electrically conductive interconnection section is formed such that it electrically connects the electrically conductive pad section to one side or both sides of the light emitting diode section.

Therefore, it is an object of the present invention to provide a light emitting diode device which has at least one electrically conductive interconnection section as stated above, a manufacturing method thereof, and a light emitting unit with such a light emitting diode device.

To achieve this objective, there is provided a light emitting diode device in accordance with one aspect of the present invention, the light emitting diode device comprising: (a) a light emitting diode section; (b) an electrically conductive pad section being disposed outside the light emitting diode section and being electrically connected to an external power source; and (c) at least one electrically conductive interconnection section for connecting the electrically conductive pad section to one side or both sides of the light emitting diode section.

In accordance with another aspect of the present invention, there is provided a light emitting unit with the above-mentioned light emitting diode device.

In accordance with another aspect of the present invention, there is provided a method for manufacturing a light emitting diode device, the method comprising the steps of: (a) forming at least one electrically conductive pad section on a substrate; (b) bonding a prepared light emitting diode section on the substrate; and (c) forming at least one electrically conductive interconnection section for connecting the electrically conductive pad section to one side or both sides of the light emitting diode section.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view showing a structure of a low-output GaN-based light emitting diode device;

FIG. 2 is a sectional view showing a structure of a high-output GaN-based flip chip light emitting diode device;

FIGS. 3a and 3b are sectional views of a light emitting diode device, in which a light emitting diode section surface with a wire directly connected thereto is coated with a fluorescent substance in a different manner from each other;

FIG. 4 is a schematic view showing a process of coating a fluorescent substance on a light emitting diode section surface to which an electrically conductive pad section is connected through an electrically conductive interconnection section, which is the form of a thin film deposited by patterning, according to the present invention;

FIG. 5 is a sectional view of a unit chip of a GaN-based LLO (Laser Lift-Off) light emitting diode device with a fluorescent substance coated on a light emitting diode section to which an electrically conductive pad section is connected through an electrically conductive interconnection section, which is the form of a thin film deposited by patterning, according to the present invention;

FIG. 6 is a top plan view of a conventional GaN-based LLO light emitting diode device with a wire bonding section existing over a light emitting diode section;

FIG. 7 is a top plan view of a light emitting diode device with an electrically conductive pad section disposed outside a light emitting diode section in accordance with a preferred embodiment of the present invention, which is obtained by depositing an ohmic contact metal layer in the form of two patterns not connected with each other, providing a transparent insulation layer on connection paths along which interconnection sections connecting the ohmic contact metal layer to the electrically conductive pad section will be formed, and then forming the interconnection sections on the transparent insulation layer such that they are disposed on both sides of the ohmic contact metal layer patterns;

FIG. 8 is a top plan view of a light emitting diode device with an electrically conductive pad section disposed outside a light emitting diode section in accordance with a preferred variant of the present invention, which is obtained by depositing an ohmic contact metal layer in the form of two patterns not connected with each other, providing a transparent insulation layer on connection paths along which interconnection sections connecting the ohmic contact metal layer to the electrically conductive pad section will be formed, and then forming the interconnection sections on the transparent insulation layer such that they are disposed on one side of the ohmic contact metal layer patterns;

FIG. 9 is a top plan view of a light emitting diode device with an electrically conductive pad section disposed outside a light emitting diode section in accordance with another preferred variant of the present invention, which is obtained by depositing an ohmic contact metal layer in the form of one pattern, and forming only one interconnection section on one side of the ohmic contact metal layer pattern;

FIG. 10 is a top plan view of a light emitting diode device with an electrically conductive pad section disposed outside a light emitting diode section in accordance with another preferred variant of the present invention, which is obtained by forming a transparent insulation layer on a connection path of an interconnection section connecting an ohmic contact metal layer to the electrically conductive pad section before the ohmic contact metal layer is deposited, and then simultaneously forming the interconnection section and the ohmic contact metal layer;

FIG. 11 is a schematic view showing a manufacturing process of a high-output LLO light emitting diode device with an interconnection section according to the present invention; and

FIG. 12 is a graph showing an area ratio of the electrically conductive pad section with respect to the overall area of a unit chip.

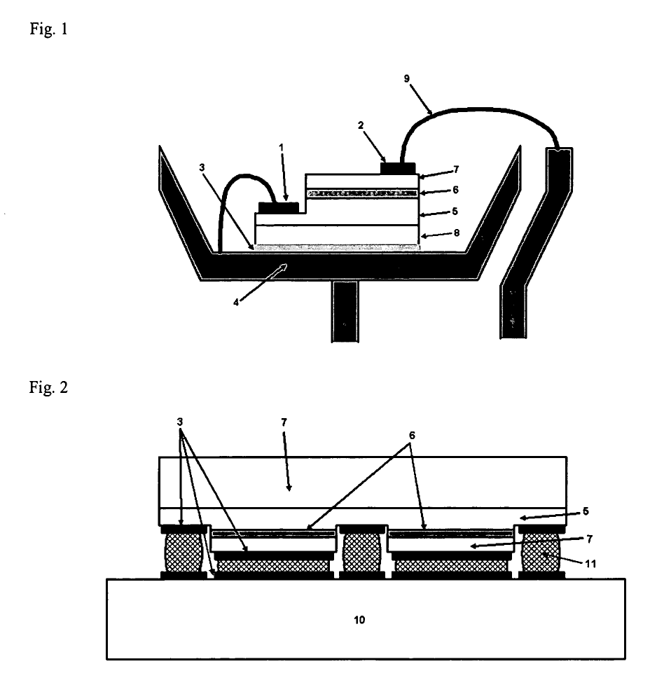

### BRIEF DESCRIPTION OF THE INDICATIONS IN THE DRAWINGS

5: n-GaN
6: multiple quantum well (MQW)
7: p-GaN
8: sapphire substrate
10: sub mount
13: n-ohmic contact layer
15: n-conductive pad section
17: conductive interconnection section
18: fluorescent substance (phosphor)
19: insulation layer

### DETAILED DESCRIPTION OF THE PREFERRED EMBODIMENT

Hereinafter, the present invention will be described in more detail.

In a conventional light emitting diode device, a wire bonding section causes the above-mentioned problems because it is disposed over a light emitting diode section. Contrary to this, the present invention is characterized in that the wire bonding section is disposed outside the light emitting diode section.

That is, dissimilarly to the conventional light emitting diode in which an ohmic contact metal layer located on the light emitting diode section is directly wire bonded to a wire, an electrically conductive pad section 15 for wire bonding is disposed outside the light emitting diode section and then is electrically connected to one side or both sides of the light emitting diode section as shown in FIG. 5. In the present invention, such an electrical connection structure is referred to as an interconnection section.

Various effects which can be derived from the structural characteristic of the present invention are as follows:

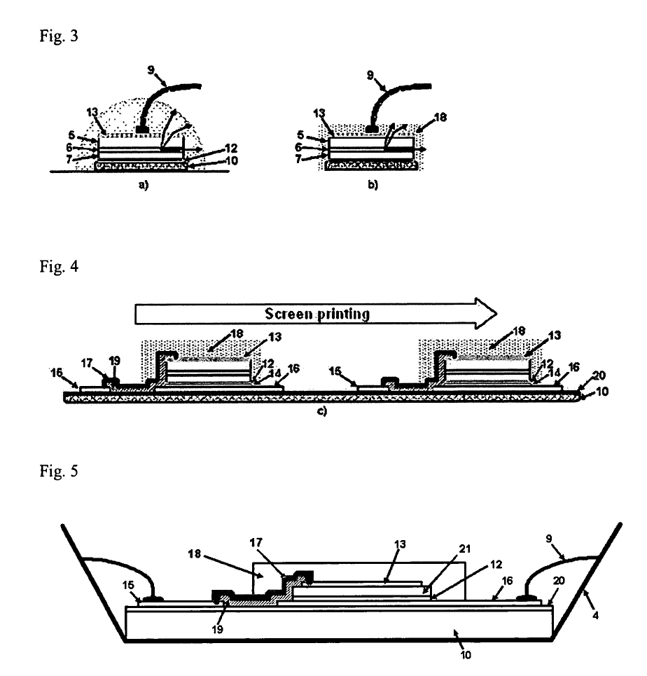

1) A conventional light emitting diode device is manufactured in such a manner that an ohmic contact metal layer located on a light emitting diode section is directly wire bonded to a wire and thus the light emitting diode device finally has a structure in which a wire bonding section exists over the light emitting diode as shown in FIGS. 3a and 3b. Owing to the wire bonding section existing over the light emitting diode, not only a process of subsequently coating a uniform and thin fluorescent substance 18 becomes difficult, but also there occurs a difference in a traveling distance of light passing through the fluorescent substance 18 because the coating layer fluorescent substance 18 has a sphere-like shape due to a surface tension of epoxy or silicon. Thus, the fluorescent substance 18 absorbs light in different extents dependent upon the traveling distance of light therethrough, which results in color non-uniformity and lowering of light output. Also, as shown in FIG. 3b, a difference in light absorption by the fluorescent substance may be reduced by coating the fluorescent substance in the form of a thin film, but a location of the wire bonding pad is basically unchanged and thus the wire bonding pad remains located over the light emitting diode section. On account of this, not only is the inconvenience in coating the fluorescent substance 18 maintained, but also cost required for the coating increase and the coating process suffers many difficulties.

Contrary to this, by fundamentally shifting the wire bonding section to the outside of the light emitting diode section according to the present invention, it is easy to coat a uniform and thin fluorescent substance over the light emitting diode section, which minimizes a light loss through the fluorescent substance.

2) In addition, steric hindrance due to the wire bonding section are removed from the light emitting diode section surface, so unit chips which are regularly arranged on a substrate 10 can be coated with the fluorescent substance at a time by means of a screen printing method, etc. as shown in FIG. 4, which can promote an economical efficiency through reduction in the unit cost of manufacture and mass production.

3) Furthermore, the present invention reduces a vertically emitted light-covering area, thereby enabling a light extraction efficiency to be fundamentally enhanced.

The interconnection section according to the present invention functions like electrical connection wiring and is preferably in the form of a thin film which is deposited by patterning. Preferably, material constituting the interconnection section may be Ag, Cu, Au, Al, Ti, Ni, Cr, Rh, Ir, Mo, W, Co, Zn, Cd, Ru, In, Os, Fe, Sn or a mixture thereof (alloy), but it need not be limited to them so long as it is electrically conductive.

The interconnection section is a part of electrical connection lines existing within the light emitting diode device, and its one end is connected to the electrically conductive pad section located outside the light emitting diode section and the other end is connected to one side or both sides of the light emitting diode section, in particular, to an upper portion of the light emitting diode section.

The electrically conductive pad section, to which the interconnection section of the present invention is connected, can be connected to an external power source, for example, a lead frame through a wire 9. In the scope of the present invention, besides the connection through the wire 9, the electrically conductive section may be connected to the external power source in the same manner as the interconnection section, that is, by patterning of a deposited thin film.

The electrically conductive pad section located outside the light emitting diode section may exist on the same substrate on which the light emitting diode section is bonded, and is preferably at least one, if possible, at least two in number. Preferably, material constituting the electrically conductive pad section may be Au, Ag, Cu, Al, Cr, Ti, Ni, In, Pt or a mixture thereof, but it also need not be limited to them so long as it is electrically conductive.

The substrate, on which the electrically conductive pad section is located, may also be electrically conductive, and the electrically conductive pad section is electrically isolated from the electrically conductive substrate by means of an insulation layer which is formed on the substrate. One side of the light emitting diode section can be electrically connected to the electrically conductive pad section through the interconnection section, and the other side to be bonded on the substrate can be electrically connected to the external power source in such a manner that it is connected to the wire, which is in turn connected to the external power source, through another electrically conductive pad section neighboring a lower portion of the light emitting diode section.

In order to prevent an electrical short circuit, an insulation layer must be formed on a connection path along which the electrically conductive pad section is connected to the light emitting diode section surface, and the interconnection section is formed on that insulation layer. However, the insulation layer is not formed in a contact portion of the light emitting diode section, which is connected to the interconnection section, so as to establish an electrical connection between the interconnection section and the light emitting diode section.

The insulation layer is preferably transparent in order to minimize the absorption of light coming out of sides and an upper portion of the light emitting diode device. Any component may be used for the insulation layer without limitation so long as it has electrical non-conductivity and transparency. For example, the component of the insulation layer includes silicon oxide (SiO₂), silicon nitride (SiNₓ) and the like. Also, there is no limit to the width of the insulation layer and the interconnection section, but it is preferred that the width of the insulation layer is larger than that of the interconnection section and the width of the interconnection section is smaller than that of the wire.

The one side or both sides of the light emitting diode section, to which the electrically conductive pad section is connected through the interconnection section, is/are preferably a light emitting diode section surface/light emitting diode surfaces which does/do not neighbor the substrate when the light emitting diode section is mounted on the substrate. In particular, it is preferred that the light emitting diode section surface(s) is/are connected to an ohmic contact metal layer in order to enhance a light emission efficiency through resistance reduction.

At this time, the ohmic contact metal layer may be an n-ohmic contact metal layer or a p-ohmic contact metal layer according to manufacturing types of the light emitting diode device, for example, a manufacturing type for a low-output device, a mid-output device or a high-output device, a Laser Lift-Off (LLO) manufacturing type and the like. Also, the ohmic contact metal may be formed of one pattern or at least two separated patterns, each of which can be connected to at least one interconnection section. Ordinary metals known in the art, such as Ni, Au, Pt and the like, may be used as the ohmic contact metal, and a further metal layer for light reflection such as an Ag layer, an Al layer or a Cr layer may be used. If necessary, a metal layer for improving the bonding of the ohmic contact metal may be added.

In the light emitting diode device including at least one electrically conductive interconnection section according to the present invention, a single layer of a fluorescent substance or a mixture layer of a molding material and a fluorescent substance may be formed partially or wholly on surfaces of the light emitting diode section and the interconnection section. The fluorescent substance layer may also formed partially or wholly on a surface of the electrically conductive pad section, but it is preferred that the fluorescent substance layer is formed partially on the surface of the electrically conductive pad section in order to facilitate wire bonding between the electrically conductive pad section and the external power source. If the fluorescent substance layer is formed wholly on the surface of the electrically conductive pad section, then wire bonding may be performed by perforating a hole through the fluorescent substance layer.

Additional advantages, objects, and features of the invention will be set forth in part in the description which follows and in part will become apparent to those having ordinary skill in the art upon examination of the following or may be learned by practicing the invention. The objectives and other advantages of the invention may be realized and attained by the structure particularly pointed out in the written description and claims hereof as well as the appended drawings.

Reference will now be made in detail to the preferred embodiments of the present invention, examples of which are illustrated in the accompanying drawings. Wherever possible, the same reference numbers will be used throughout the drawings to refer to the same or like parts.

Hereinafter, the present invention will be explained in more detail in connection with preferred embodiments.

FIG. 5 shows a sectional structure of a light emitting diode (LED) device in accordance with a preferred embodiment of the present invention. A pair of electrically conductive pad sections, for example, an n-type electrically conductive pad section 15 and a p-type electrically conductive pad section 16 exist on an insulation layer 20 which is formed on one surface of a substrate, that is, a sub-mount 30, and a p-type layer 7, an active layer (light emitting layer) and an n-type layer 5 of a light emitting diode section are successively formed in a stack structure on the p-type electrically conductive pad section 16. At this time, a p-ohmic contact metal layer 12 is bonded onto a p-type electrically conductive pad section surface adjacent to the p-type layer 7.

Ordinary sub-mounts 30 known in the art may be used as the substrate for mounting the light emitting diode section thereon, and the substrate may consist of CuW, Si, AlN ceramic, Al₂O₃ ceramic or the like. The size of the substrate may be larger than that of the light emitting diode section or may be equal to or larger than that of a sapphire substrate when the light emitting diode section is grown on the sapphire substrate.

The light emitting diode section may be formed with the p-type layer 7, the active layer (light emitting layer) and the n-type layer 5 using ordinary Groups III-V compounds known in the art, and a non-limitative example of the compounds includes GaAs, GaP, GaN, InP, InAs, InSb, GaAlN, InGaN, InAlGaN or a mixture thereof. The p-type layer 7 and the n-type layer 5 may not be doped with a p-type dopant and an n-type dopant, respectively, but are preferably doped with those dopants. The active layer (light emitting layer) may be of a single quantum well structure or a multiple quantum well (MQW) structure. Besides the above-mentioned p-type, active and n-type layers, another buffer layer may be included. By adjusting a composition of Groups III-V compounds, light emitting diodes with a long wavelength to a short wavelength can be freely manufactured, through which the present invention can be applied to all kinds of light emitting diodes without being limited to a blue nitride-base light emitting diode with a wavelength of 460 nm.

The insulation layer 20 is formed on a connection path between an n-ohmic contact metal layer 13 deposited on the uppermost layer of the light emitting diode section and the n-type electrically conductive pad section disposed outside the light emitting diode section, and an interconnection section 17 for electrically connecting the n-ohmic contact metal layer 13 to the n-type electrically conductive pad section 15 is formed on the top of the insulation layer.

The pair of electrically conductive pad sections 15, 16 are all electrically connected to an external power source, that is, a lead frame 4.

The light emitting diode device having the above-mentioned structure may be operated according to the following principle. That is, if a specific voltage is applied between the pair of electrically conductive pad sections 15, 16 through a wire 9 connected to the external power source, a cathode of the light emitting diode device is connected to the external power source through the n-type electrically conductive pad section 15, the interconnection section 17, the n-type ohmic contact metal layer 13 and the n-type layer 5, and an anode of the light emitting diode device is connected to the external power source through the p-type electrically conductive pad section 16, the p-type ohmic contact metal layer 12 and the p-type layer 7, so an electric current flows through the light emitting diode device. By this, light with energy corresponding to a band gap or an energy level difference of the active layer is emitted while electrons and holes are recombined with each other in the active layer.

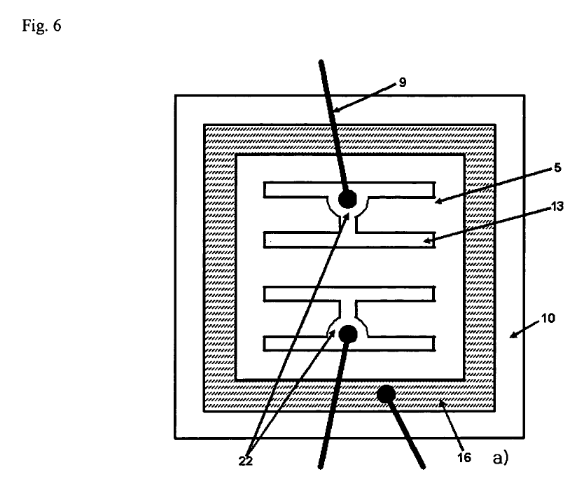

Hereinafter, a detailed description will be given for how the interconnection section 17 and connection sections connected to the interconnection section, such as the n-ohmic contact metal layer 13, the n-type pad section 15 and the p-type pad section 16, are disposed in the light emitting diode device according to the present invention with reference to FIG. 6 and FIGS. 7 to 10.

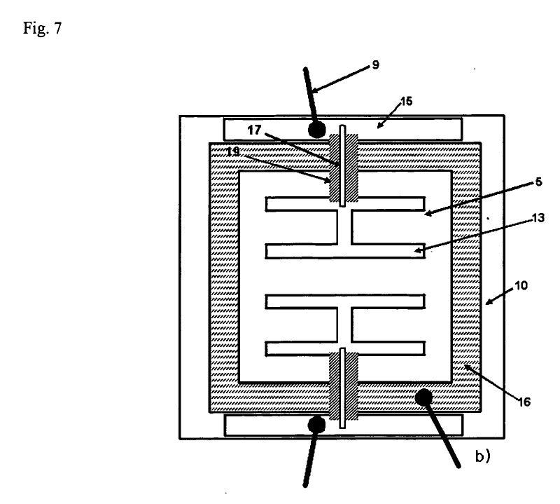

FIG. 6 is a top plan view of a conventional gallium nitride-based LLO light emitting diode device in which a wire bonding section exists over a light emitting diode section. It can be seen from the drawing that the conventional light emitting diode device has a problem of covering partially a vertical light emitting area by the wire bonding section existing over the light emitting diode section as stated above. Contrary to this, FIGS. 7 to 10 show that the electrically conductive pad sections according to the present invention is electrically connected to a light emitting diode section surface, in particular, the n-ohmic contact metal layer over the light emitting diode section through the interconnection sections 17. In actual, disposing the electrically conductive pad sections outside the light emitting diode section can promote to minimize the vertical light emitting area covered by the wire bonding section, and it can be expected to realize easy manufacturing processes and light extraction enhancement by adjusting the number and position of the interconnection sections. A detailed description thereof is as follows:

FIG. 7 is a top plan view of a light emitting diode device with an electrically conductive pad section disposed outside a light emitting diode section in accordance with a preferred embodiment of the present invention, which corresponds to a case where an ohmic contact metal layer is deposited in the form of two patterns not connected with each other, a transparent insulation layer is provided on connection paths along which interconnection sections connecting the ohmic contact metal layer to the electrically conductive pad section will be formed, and then the interconnection sections are formed on the transparent insulation layer such that they are disposed on both sides of the ohmic contact metal layer patterns.

At this time, if the width of a wire 9 is approximately 25 μm and the diameter of a ball generated during wire bonding is approximately 100 μm, the electrically conductive pad section where the ball is generated, for example, the n-type pad 15 must have a size of at least 100×100 μm². When the wire bonding section exists over the light emitting diode section as in the prior art, vertically emitted light is covered by an area of at least 100×100 μm². Contrary to this, in the light emitting diode device using the interconnection section 17 according to the present invention, an area required for the interconnection section is by far smaller than that of the wire bonding section and thus the area covering the vertically emitted light is also reduced.

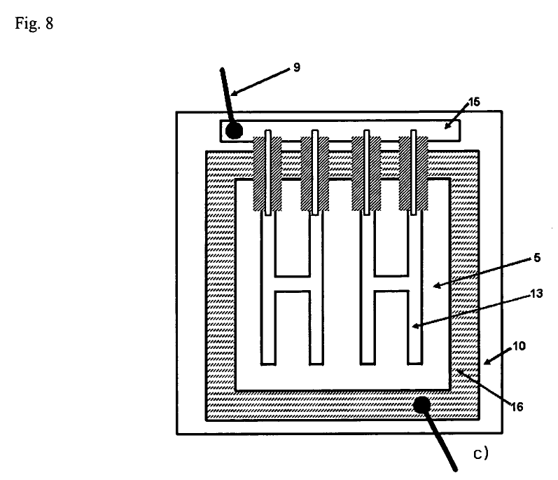

FIG. 8 shows a preferred variant of the present invention, in which an ohmic contact metal layer is deposited in the form of two patterns not connected with each other, a transparent insulation layer is provided on connection paths along which interconnection sections connecting the ohmic contact metal layer to the electrically conductive pad section will be formed, and then the interconnection sections are formed on the transparent insulation layer such that they are disposed on one side of the ohmic contact metal layer patterns.

If the electrically conductive pad section is disposed on not both sides but one side of the ohmic contact metal layer patterns as shown the drawing, it is possible to enlarge spatial margins in a process of disposing the electrically conductive pad section and unit chips and thus the disposition process can be easily performed. Also, whereas using only one interconnection section may cause an irregular distributed of light due to a voltage drop when the n-ohmic contact metal layer 13 has high resistance, such an irregular distribution of light can be prevented by use of a plurality of interconnection sections 17.

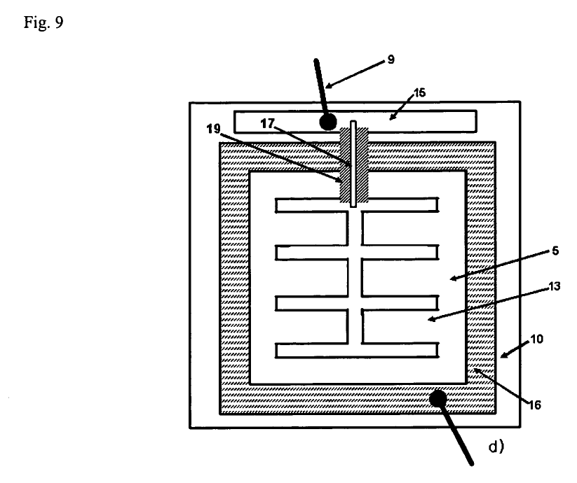

FIG. 9 shows another preferred variant of the present invention, in which an ohmic contact metal layer is deposited in the form of one pattern, and only one interconnection section is disposed on one side of the ohmic contact metal layer pattern.

Since it is advantageous to reduce the number of the interconnection sections 17 and thus the light-covering area when an upper portion of the light emitting diode section has a small area, the n-ohmic contact metal layer 13 must be deposited thickly enough to drive the light emitting diode device. To this end, all of the n-ohmic contact metal layer patterns 13 must be connected to each other. Also, since the metal itself must have low resistance so as to lower a voltage drop and thus drive the light emitting diode device at a desired current, the n-ohmic contact metal layer 13 must be deposited with a sufficiently large thickness. However, the higher output a light emitting diode has, the larger area an upper portion of the light emitting diode has, so there is a limit to prevention of the voltage drop no matter how thickly the n-ohmic contact metal layer 13 is deposited when the light emitting diode device is driven using only one interconnection section 17. Consequently, it is preferred that the number of interconnection sections 17 is at least two, and the interconnection sections 17 and the n-ohmic contact metal layer 13 are arranged such that they cover the area of the upper portion of the light emitting diode section as small as possible.

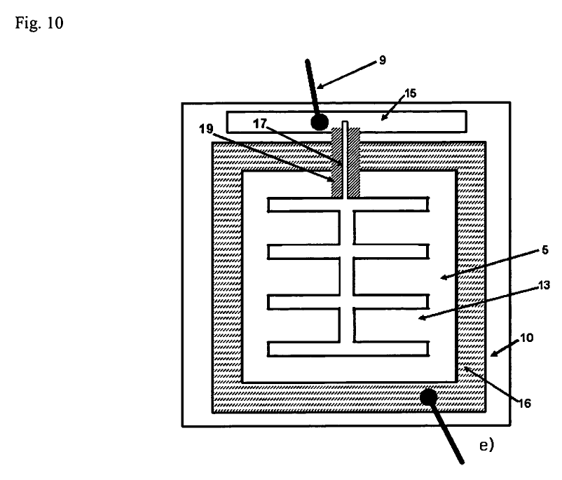

FIG. 10 shows another preferred variant of the present invention, in which a transparent insulation layer is formed on a connection path of an interconnection section connecting an ohmic contact metal layer to the electrically conductive pad section before the ohmic contact metal layer is deposited, and then the interconnection section and the ohmic contact metal layer are simultaneously formed. If the interconnection section and the ohmic contact metal layer are simultaneously formed in this way, process steps can be simplified to curtail the cost of production.

The light emitting diode device according to the present invention has no limitation on a manufacturing type, an output grade and a light emitting wavelength range. Thus, the light emitting diode device of the present invention may be manufactured in various ways, but a preferred embodiment of the manufacturing method includes the steps of: (a) forming at least one electrically conductive pad section on a substrate; (b) bonding a prepared light emitting diode section on the substrate; and (c) forming at least one electrically conductive interconnection section for electrically connecting the electrically conductive pad section to one side or both sides of the light emitting diode section.

1) First of all, at least one, preferably at least two electrically conductive pad section(s) is/are bonded or deposited on a substrate (second substrate) such as a sub-mount in properly selected positions.

2) Subsequently, a light emitting diode section having n-type, active and p-type layers stacked on a first substrate such as a sapphire substrate is bonded on a second substrate. At this time, in a case of a low-output light emitting diode device, the first substrate is bonded adjacent to the second substrate and thus the layers of the light emitting diode section maintain its stacked order. Contrary to this, in a case of a high-output light emitting diode device or an LLO light emitting diode device, the light emitting diode section is bonded on the second substrate with its inner face facing out, that is, a light emitting diode surface of the light emitting diode section is bonded on the front surface of the second substrate. In addition, in a case of the low-output light emitting diode device, the light emitting diode section is bonded in a state where it is grown on the first substrate, for example, a sapphire substrate. However, in a case of the LLO light emitting diode device, the light emitting diode section grown on the sapphire substrate is bonded in a reverse order and then the sapphire substrate is removed by means of laser irradiation. That is, in a final light emitting diode device, the sapphire substrate does not exist.

Since a material which can be used for bonding the light emitting diode section on the second substrate must supply a current to the light emitting diode therethrough and easily discharge heat generated in the light emitting diode, any materials easy to be bonded at a low temperature below 300° C. may be used without limitation. A non-limitative example thereof includes AuSn, AgSn, PbSn, Sn, silver paste or the like.

3) In order to electrically connect the electrically conductive pad section to one side or both sides of the light emitting diode section, preferably an ohmic contact metal layer formed on the light emitting diode section surface, which exist in the same plane of the second substrate, at least one interconnection section made of conductive metal is formed by means of thin film deposition and patterning. For reference, before the interconnection section is formed, a transparent insulation layer is formed on a connection path along which the interconnection section will be formed. Preferably, the width of the insulation layer is equal to or larger than that of the interconnection section.

At this time, the light emitting diode section surface may be formed with prominence and depression so that plenty of light can be escaped from the light emitting diode section surface by increasing an angle of total reflection. Also, when the ohmic contact metal layer is deposited on the surface of the light emitting diode section, it may be formed in the form of one pattern or at least two separated patterns as shown in FIGS. 7 to 10. Furthermore, the deposition of the ohmic contact metal layer may be realize using a shadow mask process as well as a photolithography process, and it is possible to properly select the process for realizing the deposition of the ohmic contact metal layer dependent upon the width of the leading wire.

In the light emitting diode device with at least one interconnection section according to the present invention, a wire bonding step for connecting the electrically conductive pad to an external power source, for example, a lead frame, and a step of coating a sole fluorescent substance or a mixture of a fluorescent substance and a molding material may be performed in sequence or in reverse sequence. Subsequently, the light emitting diode section bonded on the second substrate may be separated into unit chips or a light emitting diode section separated into unit chips may be bonded on the second substrate. Such a chip separation step is not limited to this and the unit chips may be properly arranged according to user's intention or the degree of easiness of the manufacturing process.

One preferred embodiment of methods for manufacturing a light emitting diode device using an interconnection section according to the present invention is a Laser Lift-Off (LLO)-type method. As an example, the LLO-type method includes the steps of: (a) depositing a p-ohmic contact metal layer on a p-type layer of a light emitting diode section grown on a first substrate; (b) polishing the rear surface of the first substrate; (c) separating the first substrate, on which the light emitting diode section is grown, into unit chips; (d) bonding the p-ohmic contact metal layer surface of light emitting diode section in the first substrate, which is separated into unit chips, on a first electrically conductive pad section among two electrically conductive pad sections formed on a second substrate; (e) irradiating a laser beam on the first substrate surface of the unit chip bonded on the second substrate to remove the first substrate; (f) depositing an n-ohmic contact metal layer on an n-type layer of the light emitting diode section, which is exposed as the first substrate is removed; (g) forming an insulation layer on a connection path connecting an n-ohmic contact metal layer surface to a second electrically conductive pad section located on the second substrate and then forming at least one interconnection section for connecting the n-ohmic contact metal layer surface to the electrically conductive pad section; and (h) wire bonding to connect the first and second electrically conductive pad sections to an external power source, respectively and then coating a fluorescent substance or treating a molding material mixed with a fluorescent substance.

FIG. 8 shows partial steps of the above-mentioned LLO-type manufacturing method, which is based on boding wholly the first substrate, for example, a sapphire substrate on the second substrate and then removing the sapphire substrate by means of laser irradiation. The respective method steps are as follows:

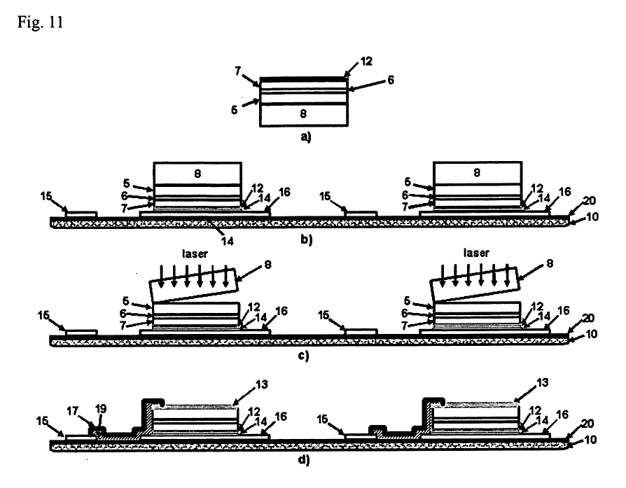

(1) P-Type Ohmic Contact Formation Step (cf. FIG. 11a)

After a wafer, in which a light emitting diode section, for example a GaN-based light emitting diode crystal structure is grown on a sapphire substrate, is initially washed out, a p-type ohmic contact metal layer is formed on an upper p-type GaN surface of the wafer by vacuum deposition and then heat treatment is performed to complete a p-type ohmic contact.

(2) Polishing Treatment of Sapphire Substrate Surface

In order to form a mirror surface enabling laser beams to easily transmit the sapphire substrate, the sapphire substrate with a thickness of about 430 μm is polished to reduce the thickness of the sapphire substrate to about 80 to 100 μm.

(3) Unit Chip Formation Step (cf. FIG. 3a)

After the light emitting diode section is boned on a sub-mount substrate and before the sapphire substrate is removed, the light emitting diode section is separated into unit chips through scribing/breaking processing.

(4) Sub-Mount Substrate (Second Substrate) Bonding Step (cf. FIG. 11b)

In a case of a high-output light emitting diode, a sub-mount substrate is used for enhancing a heat discharging efficiency. At this time, an insulation layer 20 for preventing a short circuit is deposited over the sub-mount substrate 10, and electrically conductive pad sections, for example, an n-type pad section 15 and a p-type pad section 16 are formed on the insulation layer 20.

The light emitting diode section is put upside down on the sub-mount substrate such that the polished sapphire substrate climbs upward, and the p-type ohmic contact metal layer surface of the light emitting diode section is bonded on the sub-mount substrate or the p-type pad section 16 located on the sub-mount substrate. In a case of bonding the unit chips on the sub-mount 10, it is preferred to regularly arrange the unit chips at a distance of several hundreds μm between the chips in consideration of a dicing process of the sub-mount substrate 10 to be performed later (cf. FIG. 11b).

(5) Laser Irradiation (cf. FIG. 11c)

Laser is irradiated toward sapphire surfaces of the chips to remove the sapphire substrates. If the laser is irradiated, laser beams transmitting the sapphire substrate are absorbed into a light emitting section, for example, a gallium nitride section to decompose the gallium nitride existing in an interface region between the sapphire and the gallium nitride section. Thus, the sapphire substrate is separated from the light emitting diode crystal structure while metal gallium and nitrogen gas are produced.

(6) N-Type Ohmic Contact Formation Step (cf. FIG. 11d)

An n-type ohmic contact metal layer 13 is deposited on an n-type layer, preferably an n-type GaN surface of the light emitting diode section, which is exposed as the sapphire substrate is removed. If necessary, a polishing process or a dry (or wet) etching process may be performed before the n-type ohmic contact metal layer is deposited.

At this time, the metal gallium which has been produced during the GaN decomposition exists on the exposed GaN surface. Since such a metal gallium layer reduces light emitted from the light emitting diode, it is removed using hydrochloric acid. Thereafter, as the case may be, the undoped GaN layer is etched through a dry (or wet) etching process to expose an n⁺-GaN layer, and a metal layer for the n-ohmic contact formation (e.g., metal of a Ti/Al series) may be vacuum-deposited if necessary.

(7) Interconnection Section Formation

A transparent insulation layer is formed on a connection path between the top portion of the light emitting diode section, that is, the exposed n-type layer and the n-type electrically conductive pad section located on the electrically conductive substrate, preferably between the n-ohmic contact metal layer and the n-type electrically conductive pad section, and then at least one interconnection section is formed on the insulation layer by means of thin film deposition and patterning using electrically conductive metal.

(8) Wire Bonding Step

Gold wire bonding for electrically connect the n-type electrically conductive pad section to an external power source, e.g., a lead frame is performed, and the p-type electrically conductive pad section is also connected to the external power source through wire bonding. At this time, the connection between the n-type electrically conductive pad section and the external power source may be effected by means of thin film deposition and patterning.

(9) Fluorescent Substance Coating or Molding Material Treatment

Finally, a molding material such as epoxy or a molding material mixed with a fluorescent substance is coated. In this way, the manufacture of the light emitting diode device is completed. If necessary, it is possible to perform steps (8) and (9) in reverse sequence.

Although the above-mentioned description of the manufacturing method supposes a case of a high-output light emitting diode device, the present invention can also be applied to a low-output light emitting diode device. A preferred embodiment of a method for manufacturing a low-output light emitting diode device includes the steps of: (a) etching a light emitting diode section grown on a first substrate to expose an n-type layer thereof and then depositing an n-ohmic contact metal layer on the n-type layer; (b) depositing a p-ohmic contact metal layer on a p-type layer at the top of the light emitting diode section; (c) polishing the substrate surface of the first substrate and then separating the first substrate into unit chips; (d) bonding a first substrate surface of the separated unit chip on a second substrate formed with an electrically conductive pad section; (e) forming an insulation layer on a connection path connecting an p-ohmic contact metal layer surface to the electrically conductive pad section located on the second substrate and then forming at least one interconnection section for connecting the p-ohmic contact metal layer surface to the electrically conductive pad section; and (f) wire bonding to connect the electrically conductive pad section to an external power source and then coating a fluorescent substance or treating a molding material mixed with a fluorescent substance. At this time, it is possible to properly change the order of the unit chip separation step in order to promote facilitation and simplification of the manufacturing process.

The above-mentioned embodiments of the manufacturing method of the light emitting diode device are only preferred manufacturing examples, and the present invention should not be limited to them.

The light emitting diode device of the present invention includes not only ordinary light emitting diode devices known in the art, for example, a blue nitride-based light emitting diode device, but also light emitting diode devices with all other wavelengths. In particular, it is preferably applied to a white light emitting diode which requires the coating of a fluorescent substance (phosphor). The present invention can also be applied all kinds of light emitting diode device regardless of whether they are manufactured in a low-output type, a high-output flip type, an LLO type or other types.

In addition, the present invention provides a light emitting unit with a light emitting diode device which has the above-mentioned structure or is manufactured by the above-mentioned method. The light emitting unit includes all kinds of light emitting unit having a light emitting diode device, for example, an illuminator, an indicating unit, a sterilizer lamp, a display unit and so forth.

### EXAMPLE 1

### Area Analysis of Wire Bonding Pad (Electrically Conductive Pad) for Wire 9 According to Change of Chip Area

FIG. 9 is a graph showing a ratio of an area occupied by the bonding pad for the wire 9 according to the change of the overall chip area. That is, FIG. 9 graphically shows by calculation how much the bonding pad existing over the light emitting diode covers light vertically emitted from the light emitting diode. In FIG. 9, since there is little difference between an area of covering the vertically emitted light by the wire 9 in a case where the wire bonding is performed directly in an upper portion of the light emitting diode and an area of covering the vertically emitted light by the interconnection section 17 in a case of using the interconnection section 17 structure, the difference between the two cases was neglected.

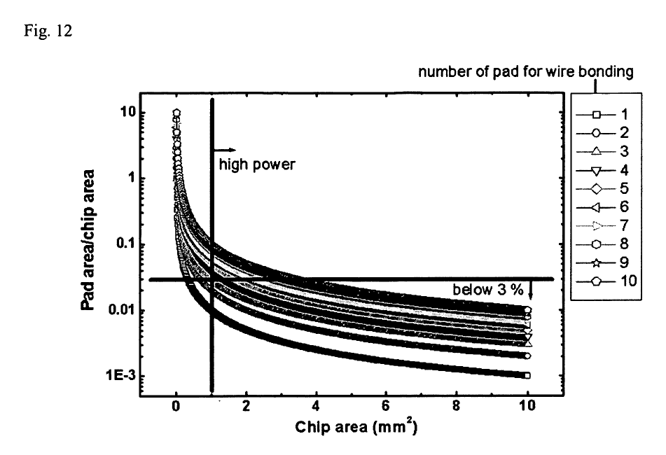

The number of the wire bonding pads varied between 1 and 10, and two conditions were considered for the area analysis. One of them is a condition where the covering area ratio with respect to the overall chip area is below 3%, and the other is a condition where the overall chip area is above 1×1 mm² as generally applied to a high-output light emitting diode. In the 1×1 mm² chip, the condition of the covering area ratio below 3% is satisfied if the number of the pads is 3 or less, and 4 or more pads occupy the covering area ratio of 3% or more. In actual, since the 1×1 mm² chip can be sufficiently driven by a current which is supplied through two pads in the arrangement of the ohmic contact metal layer as shown in FIG. 7 and the condition of the covering area ratio below 3% can be satisfied only if the number of the pads is 3 or less, the 1×1 mm² chip device can be driven by 2 or 3 bonding pads. However, if the chip area is above 4 mm², the area ratio occupied by the bonding pad is below 3% even if the number of the bonding pads is 10. That is, the effect of covering the vertically emitted light is insignificant. When the covering area ratio must be far less than 3%, the number of the pads has only to be selected according to FIG. 12.

As described above, according to a light emitting diode device of the present invention, a wire bonding section is disposed outside a light emitting diode section by use of an interconnection section, so not only it is easy to uniformly coat a fluorescent substance, but also an area covering vertically emitted light can be reduced to enhance a light extraction efficiency of the light emitting diode device.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A light emitting diode device comprising:
(a) a light emitting diode section;
(b) an electrically conductive pad section being disposed outside the light emitting diode section and being electrically connected to an external power source; and
(c) at least one electrically conductive interconnection section for connecting the electrically conductive pad section to one side or both sides of the light emitting diode section.

2. The light emitting diode device as claimed in claim 1, wherein the interconnection section is patterned by thin film deposition).

3. The light emitting diode device as claimed in claim 1, wherein the interconnection section is made of at least one metal element selected from the group consisting of Ag, Cu, Au, Al, Ti, Ni, Cr, Rh, Ir, Mo, W, Co, Zn, Cd, Ru, In, Os, Fe and Sn.

4. The light emitting diode device as claimed in claim 1, wherein the electrically conductive pad section is connected to the external power source through a wire.

5. The light emitting diode device as claimed in claim 1, wherein at least one electrically conductive pad section is provided.

6. The light emitting diode device as claimed in claim 1, wherein the electrically conductive pad section is made of at least one metal element selected from the group consisting of Au, Ag, Cu, Al, Cr, Ti, Ni, In and Pt.

7. The light emitting diode device as claimed in claim 1, wherein the light emitting diode section and the electrically conductive pad section are located on the same substrate.

8. The light emitting diode device as claimed in claim 7, wherein the substrate is an electrically conductive substrate, the electrically conductive pad section is electrically insulated from the substrate by means of an insulation layer, one side of the light emitting diode section is electrically connected to the external power source through a wire or the electrically conductive substrate, and the other side of the light emitting diode section is electrically connected to the electrically conductive pad section through the interconnection section.

9. The light emitting diode device as claimed in claim 1, wherein an insulation layer is formed on a connection path along which the interconnection section connects a surface of the light emitting diode section to the electrically conductive pad section, the interconnection section is formed on the insulation layer, a contact portion of the light emitting diode section is electrically connected to the interconnection section.

10. The light emitting diode device as claimed in claim 9, wherein the insulation layer is transparent.

11. The light emitting diode device as claimed in claim 9, wherein the width of the insulation layer is wider than that of the interconnection section, and the width of the interconnection section is narrower than that of the wire.

12. The light emitting diode device as claimed in claim 1, wherein the surface of the light emitting diode section, which is connected to the interconnection section, is an ohmic contact metal layer.

13. The light emitting diode device as claimed in claim 12, wherein the ohmic contact metal layer is formed as one pattern or at least two separated patterns, and the pattern(s) is (are) connected to at least one interconnection section.

14. The light emitting diode device as claimed in claim 1, wherein a fluorescent substance (phosphor) is coated on the surface of the light emitting diode section, which is connected to the interconnection section.

15. The light emitting diode device as claimed in claim 1, wherein the light emitting diode section includes an n-type layer, a p-type layer and a light emitting layer formed between the n-type layer and the p-type layer, and Groups III-V compound semiconductors are used as the layers of the light emitting diode section.

16. The light emitting diode device as claimed in claim 1, wherein the light emitting diode section is manufactured by means of a Laser Lift-Off (LLO) method.

17. A light emitting unit including the light emitting diode device according to claim 1.

18. A method for manufacturing a light emitting diode device, the method comprising the steps of:
(a) forming at least one electrically conductive pad section on a substrate;
(b) bonding a prepared light emitting diode section on the substrate; and
(c) forming at least one electrically conductive interconnection section for connecting the electrically conductive pad section to one side or both sides of the light emitting diode section.

19. The method as claimed in claim 18, further comprising the step of depositing an ohmic contact metal layer on one side or both sides of the light emitting diode section between the steps (b) and (c).

20. The method as claimed in claim 18, after step (c), further comprising the steps in sequence or reverse sequence of:
(i) connecting the electrically conductive pad section to an external power source by wire bonding;
(ii) coating partially or wholly the surfaces of the light emitting diode section and the interconnection section with a fluorescent substance (phosphor).
